(19) United States
(12) Patent Application Publication
(10) Pub. No.: US 2013/0002103 A1
(43) Pub. Date: Jan. 3, 2013

(54) NUT UTILIZED IN ELECTTRONIC DEVICE AND METHOD FOR ASSEMBLING THE ELECTRONIC DEVICE

(75) Inventor: LIANG-TIAN PENG, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/328,041

(22) Filed: Dec. 16, 2011

(30) Foreign Application Priority Data
Jun. 29, 2011 (CN) 201110179264.4

(51) Int. Cl. H05K 5/02; H05K 13/00; F16B 37/00

(52) U.S. Cl. 312/223.1; 411/82.1; 156/66

(57) ABSTRACT

An electronic device includes a housing and a nut. The housing defines a fixing hole. The nut is located in the fixing hole. The nut is shaped to fit in the housing and leave a receiving space. Glue is used in the receiving space for fixing the nut to the housing.

### BACKGROUND

1. Technical Field

This disclosure relates to nuts, particularly to a nut used to assembly an electronic device.

2. Description of Related Art

An electronic device such as a mobile phone, or a personal digital assistant, includes a front housing and a rear housing assembled to the front housing. A way to assemble the front housing to the rear housing is to first embed a nut into the first housing by a hot melt process, the second housing defines a mating hole; a screw is then passed through the mating hole and screwed into the nut so the first housing and the second housing are assembled together. However, the first housing is subjected to a high temperature during the embedding of the nut to the first housing by the hot melt process, as a result, the first housing may suffer deformation and a precise embedding of the nut to the first housing is not always achieved.

Therefore, there is a room for improved in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary nut, an electronic device using the nut and a method for assembling the electronic device. Moreover, in the drawings, like reference numerals designate their respective parts throughout the several views. Wherever possible, the same reference numbers are used throughout the drawings to refer to the same or like elements of an embodiment.

FIG. 1 is an exploded view of an exemplary embodiment of an electronic device including a nut and a housing.

FIG. 2 is an assembled view of the electronic device of FIG. 1.

FIG. 3 is a cross sectional view of the electronic device of FIG. 2 along the line of III-III.

FIG. 4 is a cross sectional view of the electronic device of FIG. 2 along the line of IV-IV.

### DETAILED DESCRIPTION

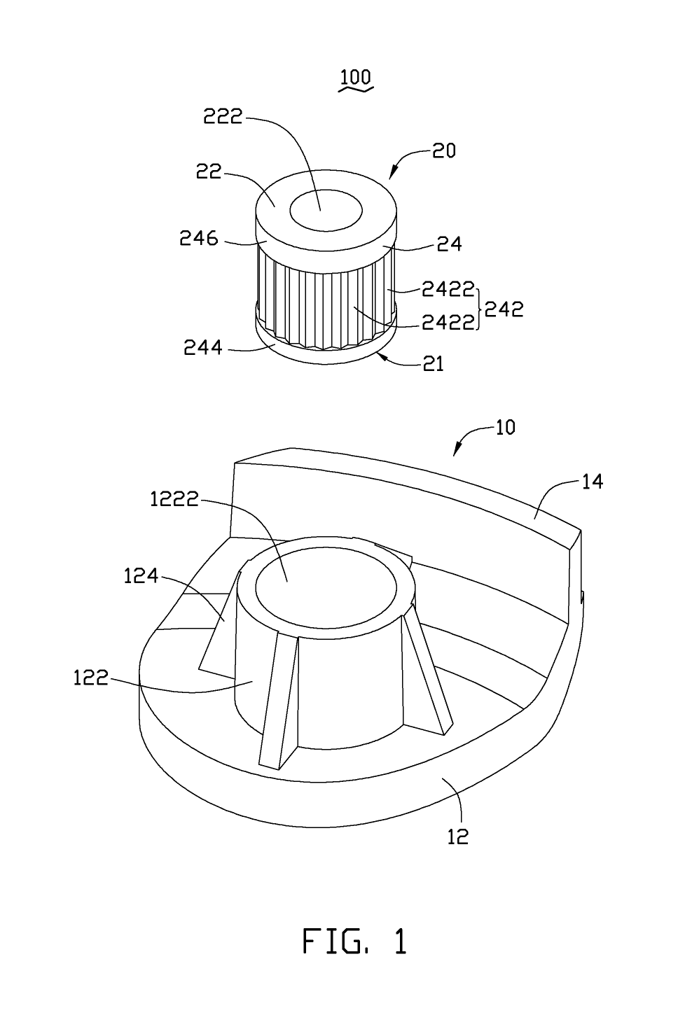

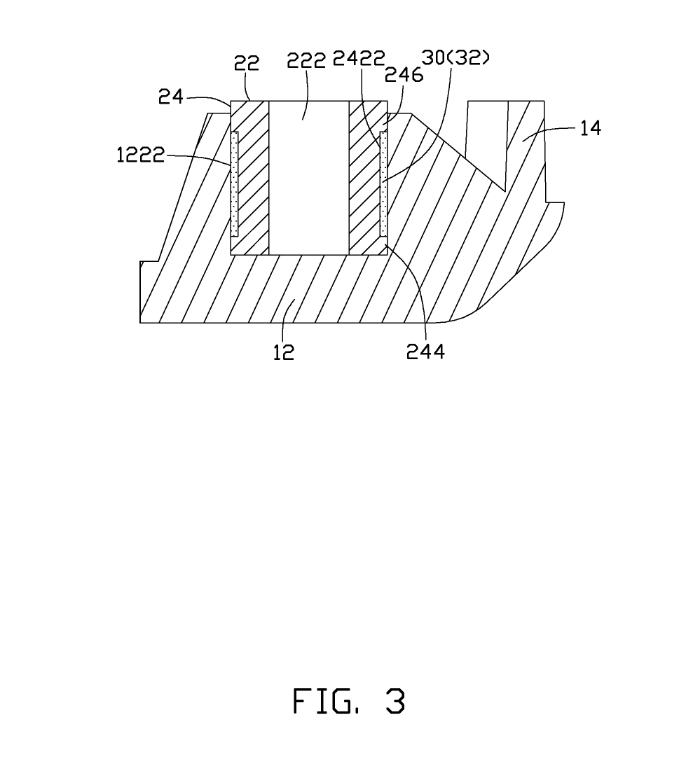

Referring to FIG. 1, an exemplary embodiment of an electronic device 100, such as a mobile phone, includes a housing 10 and a nut 20 embedded into the housing 10 by an adhesive such as glue 30 (see FIG. 3).

The housing 10 includes a bottom panel 12 and a sidewall 14. A fixing pole 122 and a plurality of ribs 124 protrude from the bottom panel 12. The ribs 124 surround and support the fixing pole 122 on the bottom panel 12. The fixing pole 122 defines a fixing hole 1222 for mounting the nut 20. To facilitate the mounting of the nut 20 in the fixing hole 1222, the fixing hole 1222 may be slightly larger than the nut 20.

The nut 20 is a hollow cylinder, and includes a first end 21, a second end 22 and a peripheral surface 24 connecting the first end 21 and the second end 22. The nut 20 defines a longitudinal threaded through hole 222. A first flange 244 protrudes from the peripheral surface 24 at the first end 21 and a second flange 246 is at the second end 22. The peripheral surface 24 further defines a receiving space 242 which includes a plurality of flutes or grooves 2422 longitudinally defined. The receiving space 242 retains the glue 30. The first flange 244 and the second flange 246 both retain the glue from escaping and spilling during curing, to retain the nut 20 precisely and permanently in the fixing hole 1222.

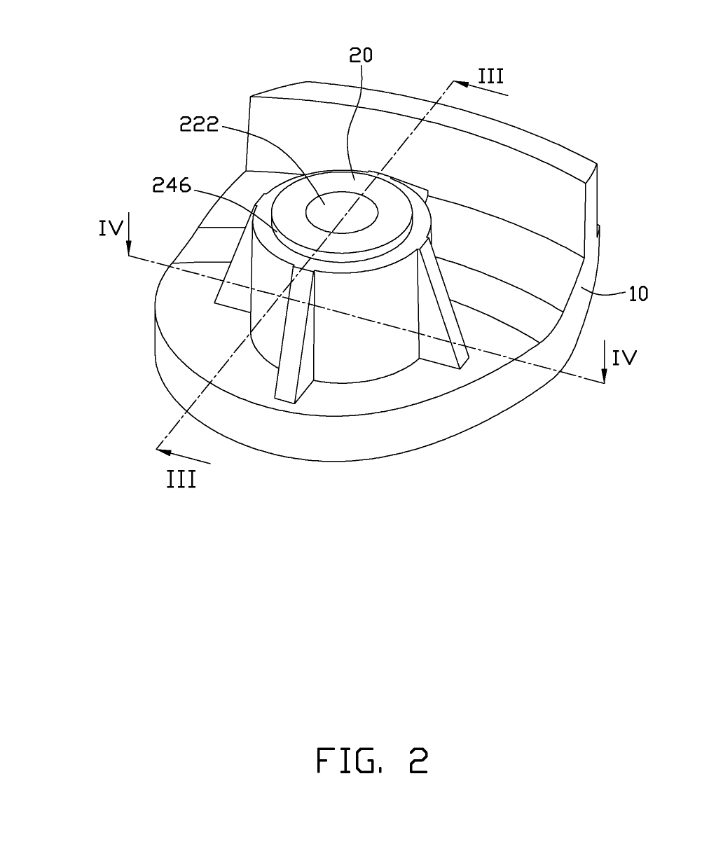

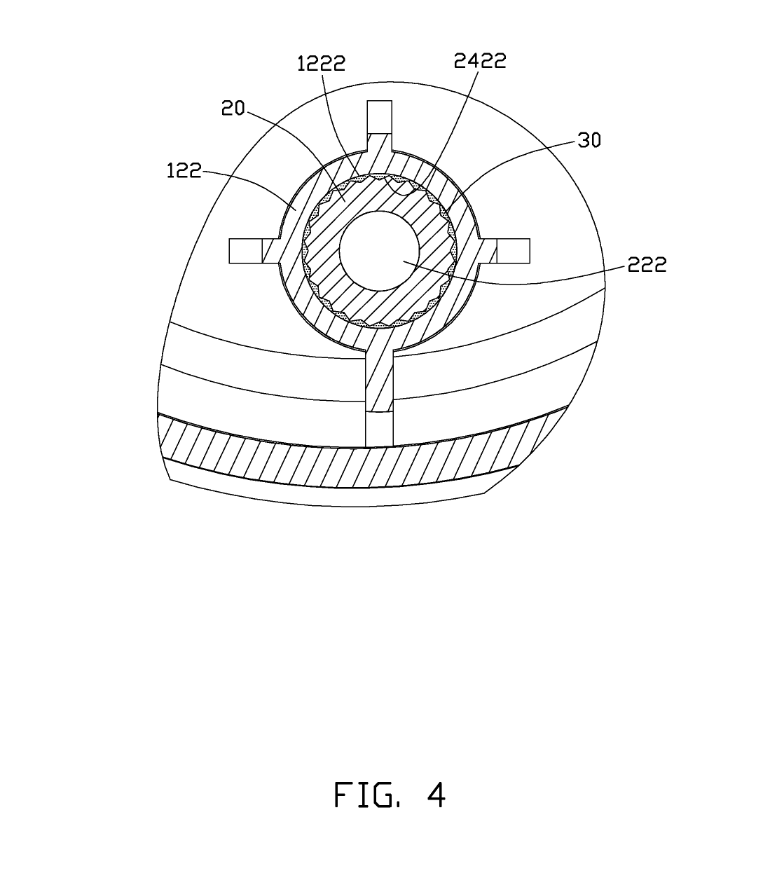

Referring to FIGS. 2-4, in assembly, the glue is applied to the grooves 2422, the glue 30 may be quick drying. The nut 20 is quickly inserted in the fixing hole 1222. The glue 30 is cured to form a plurality of solid fixing elements 32, each of which is locked in a groove 2422, and all the solid fixing elements 32 are secured between the first flange 244 and the second flange 246. Additionally, the solid fixing elements 32 adhere to the housing 10, so the nut 20 is retained to the housing 10 by the combination of the solid fixing elements 32 and the first, second flanges 244, 246, to yield an assembly of the electronic device 100.

In the above electronic device 100, the cured glue 30 (as the fixing elements 32) is between the first flange 244 and the second flange 246 so the fixing elements 32 keep the second flange 246 captive to prevent the nut 20 from separating from the housing 10. Additionally, the fixing elements 32 act to prevent the nut 20 from rotating in the fixing hole 1222 relative the housing 10. Furthermore, the use of glue in assembling the nut 20 to the housing 10, which cures at substantially lower temperatures than would be used during the hot melt process avoids any high temperature, such as that of the hot melt process, inflicted on the housing 10. The housing 10 will not be deformed and the nut 20 can be precisely embedded into the housing 10.

It is to be further understood that even though numerous characteristics and advantages of the exemplary embodiments have been set forth in the foregoing description, together with details of structures and functions of various embodiments, the disclosure is illustrative only, and changes may be made in detail, especially in the matters of shape, size, and arrangement of parts within the principles of the exemplary invention to the full extent indicated by the broad general meaning of the terms in which the appended claims are expressed.

What is claimed is:

1. A nut comprising a first end, a second end opposite to the first end, and a peripheral surface connecting the first end and the second end, the nut defining a threaded hole longitudinally through the first end and the second end, the peripheral surface defining a receiving space for retaining glue.

2. The nut of claim 1, wherein the peripheral surface protrudes a first flange at the first end and a second flange at the second end, the receiving space defined between the first flange and the second flange.

3. The nut of claim 1, wherein the receiving space includes a plurality of grooves defined along an axial direction of the nut.

4. An electronic device comprising:
a housing defining a fixing hole; and
a nut located in the fixing hole, the nut comprising a first end, a second end opposite to the first end, and a peripheral surface connecting the first end and the second end, the nut defining a threaded hole longitudinally through the first end and the second end, the peripheral surface defining a receiving space;
glue retained in the receiving space for fixing the nut to the housing.

5. The electronic device of claim 4, wherein the peripheral surface protrudes a first flange at the first end and a second flange at the second end, the receiving space defined between the first flange and the second flange.

6. The electronic device of claim 4, wherein the fixing hole is slightly larger than the nut.

7. The electronic device of claim 4, wherein the receiving space includes a plurality of grooves defined in an axial direction of the nut.

8. The electronic device of claim 7, wherein the glue cures to form a plurality of solid fixing elements, each of which is retained in one of the grooves, and the solid fixing elements adhered to the housing to fix the nut to the housing.

9. A method for assembling an electronic device, the method comprising:
providing a housing defining a fixing hole
providing a nut comprising a first end, a second end opposite to the first end, and a peripheral surface connecting the first end and the second end, the nut defining a threaded hole longitudinally through the first end and the second end, the peripheral surface defining a receiving space;
placing glue in the receiving space;
inserting the nut in the fixing hole with the glue fixing the nut to the housing.

10. The method of claim 9, wherein the peripheral surface protrudes a first flange at the first end and a second flange at the second end, the receiving space defined between the first flange and the second flange.

11. The method of claim 9, wherein the fixing hole is slightly larger than the nut.

12. The method of claim 9, wherein the receiving space includes a plurality of grooves defined in an axial direction of the nut.

13. The method of claim 12, wherein the glue cures to form a plurality of solid fixing elements, each of which is retained in one of the grooves, and the solid fixing elements adhered to the housing to fix the nut to the housing.
